(19) United States
(12) Patent Application Publication
(10) Pub. No.: US 2024/0244760 A1
(43) Pub. Date: Jul. 18, 2024

(54) CARRIER STRUCTURE, METHOD FOR PRODUCING A CARRIER STRUCTURE AND DEVICE AND PRINTHEAD FOR CARRYING OUT SUCH A METHOD

(71) Applicant: ams-OSRAM International GmbH, Regensburg (DE)

(72) Inventor: Thomas Schwarz, Regensburg (DE)

(21) Appl. No.: 18/559,526

(22) PCT Filed: May 12, 2022
(86) PCT No.: PCT/EP2022/062988

§ 371 Date: Nov. 7, 2023

(30) Foreign Application Priority Data
May 18, 2021 (DE) 10 2021 112 861.7

(51) Int. Cl. H05K 3/12; H05K 1/18; H05K 3/40; H05K 13/00

(52) U.S. Cl. CPC H05K 3/1275; H05K 1/181; H05K 3/4007; H05K 13/0015; H05K 2201/10007

(57) ABSTRACT

In an embodiment a carrier structure includes at least one conductor structure configured for electrically contacting electrical components, wherein the conductor structure includes a plurality of conductor bodies, wherein at least some of the conductor bodies are in direct contact with electrically conductive first connectors, and wherein the conductor structure includes the conductor bodies and the first connectors.

### CROSS-REFERENCE TO RELATED APPLICATIONS

This patent application is a national phase filing under section 371 of PCT/EP2022/062988, filed May 12, 2022, which claims the priority of German patent application 10 2021 112 861.7, filed May 18, 2021, each of which is incorporated herein by reference in its entirety.

### TECHNICAL FIELD

A carrier structure is specified. In addition, a method for producing a carrier structure is specified. Furthermore, a device and a printhead for carrying out such a method are specified.

### SUMMARY

Embodiments provide a carrier structure which can be produced quickly and at low cost. Further embodiments provide a method for producing such a carrier structure. Yet other embodiments provide a device and a printhead by means of which such a method can be carried out in a simple and low cost manner.

According to at least one embodiment, the carrier structure is suitable for electrical components. For example, the carrier structure forms a mechanically load-bearing component for the electrical components. In particular, electrical components can be electrically contacted via the carrier structure.

The electrical components are, for example, resistors, capacitors, memory modules, integrated circuits and/or semiconductor chips, in particular optoelectronic semiconductor chips. The optoelectronic semiconductor chips are, for example, LED chips and/or laser diode chips and/or photodetector chips for generating or detecting electromagnetic radiation. The electrical components each have one or more electrical contact surfaces, for example.

According to at least one embodiment of the carrier structure, this has at least one conductor structure for the electrical contacting of the electrical components. For example, the at least one conductor structure is in electrical contact with at least one contact surface of an electrical component. The electrical contact between the conductor structure and the electrical component can be direct or via a connecting means, e.g. solder.

According to at least one embodiment, the conductor structure comprises a multiplicity of conductor bodies. Within the scope of the production tolerances, the conductor bodies have the geometrical shape of a polygon, for example. For example, the conductor bodies are designed as cuboids, in particular as cubes. The conductor bodies are preferably spherical.

A maximum extent, in particular a diameter of the conductor bodies, is between 1 μm and 50 μm, inclusive, for example. All the conductor bodies preferably have the same dimensions or the same diameter. That is to say that the diameter and/or the volume of the conductor bodies varies by at most +/−5% around a respective average.

Each conductor body comprises at least one metal, in particular one of the following metals: copper, nickel, iron, aluminum, tungsten, tin. Each conductor body is formed from one of these metals or from a mixture of these metals, for example.

It is possible for all the conductor bodies to comprise the same metals in the same proportions. Material compositions of the conductor bodies preferably differ individually or in groups from one another. It is thus possible, by mixing conductor bodies with various material compositions, to adapt one or more physical properties of the conductor structure and hence of the carrier structure. The at least one physical property is, for example, a thermal property, e.g. a coefficient of thermal expansion or a coefficient of thermal conductivity, or an electrical property of the conductor structure and thus of the carrier structure.

According to at least one embodiment, at least some of the conductor bodies are in direct contact with an electrically conductive first connecting means. In particular, each conductor body is in direct contact with the electrically conductive first connecting means. The connecting means comprises, in particular, a metal, e.g. one of the following metals: tin, indium, silver, gold, copper. The first connecting means is preferably a solder, in particular a solder containing tin, e.g. InSn, AuSn, SnAgCu.

According to at least one embodiment of the carrier structure, the conductor structure is formed by the conductor bodies together with the first connecting means. In particular, the conductor structure contains essentially no further constituents. However, it is possible for the conductor structure to have further constituents and/or impurities in small quantities which remain in the carrier structure on account of a production process, for example. However, such constituents are preferably present in such small quantities that thermal and/or electrical properties of the conductor structure or of the carrier structure are not impaired thereby.

In at least one embodiment, the carrier structure for electrical components comprises at least one conductor structure for the electrical contacting of the electrical components. The conductor structure comprises a multiplicity of conductor bodies. At least some, in particular each, of the conductor bodies are/is in direct contact with an electrically conductive first connecting means. The conductor structure is formed by the conductor bodies together with the first connecting means.

A carrier structure described here is based inter alia on the following considerations. To produce carrier structures quickly, in order to use them as prototypes for example, additive manufacturing techniques or 3D printing are often used. With these methods, it is possible to produce a prototype relatively quickly, e.g. from CAD data. With these methods, insulating materials can be applied in layers, using filament printers or stereolithography for example.

Additive metallic structures can be formed in layers by sintering or melting metal powders by means of a laser or electron beams. The structure sizes of these metal structures normally have a bottom limit imposed by a beam diameter and are usually at least approximately 100 μm. A method in which an organometallic compound is structured and then sintered by means of stereolithography is known from Vyatskikh et al., Nat. Comm. 9, 593 (2018). Structure sizes in the submicrometer range are possible here. One disadvantage of this method, however, is the very high degree of shrinkage.

The carrier structure described here is based, inter alia, on the concept of designing a conductor structure with conductor bodies, the diameter of which is between 1 μm and 50 μm, for example. In particular, the conductor structure and hence the carrier structure can be produced quickly and at low cost. This is the case, in particular because the carrier structure can be formed in part by methods which are based on inkjet printing technology. It is possible to dispense with the use of lasers. In addition to the production of prototypes of carrier structures, small batches or mass production of carrier structures described here is possible with the method described here.

With the carrier structure described here it is advantageously possible to implement conductor structures with small structure sizes, which is limited essentially by the dimensions of the conductor body. By mixing the conductor bodies with different material compositions, it is furthermore possible to produce new material properties. By mixing conductor bodies made of copper and conductor bodies made of nickel, for example, it is thus possible to adjust the thermal conductivity and the coefficient of expansion. Moreover, electrical properties can be precisely adjusted through an appropriate choice of materials for the conductor bodies. Furthermore, an appropriate choice of materials or a suitable thickness enables the conductor structures to be used for the application of electrical components in the high-current range. Another advantage consists in the fact that the conductor structure can be guided in almost any way in or on the carrier structure, thereby, in particular, making possible flat conductor track routing and a flat carrier structure.

According to at least one embodiment, the carrier structure comprises a multiplicity of insulating bodies. The insulating bodies comprise one of the following electrically insulating materials, for example: Al₂O₃, AlN, SiC, diamond, SiO₂, a glass such as Borofloat® glass or soda lime glass or a plastic. Similarly to the conductor bodies, the insulating bodies are designed as polygons or preferably of spherical design, for example. All the insulating bodies preferably have the same dimensions or the same diameter. As a further preference, the dimensions or diameters of the insulating bodies coincide with the dimensions or diameters of the conductor bodies.

According to the at least one embodiment of the carrier structure, some, in particular each, of the insulating bodies are/is in direct contact with an electrically insulating second connecting means. The second connecting means is, for example, a thermoplastic, such as PE, PET, PA, PEEK and/or a thermoset, such as silicone, epoxy or acrylate.

According to at least one embodiment, the insulating bodies, together with the second connecting means, form an electrically insulating base body of the carrier structure. The conductor structure is embedded in the electrically insulating base body, for example. The carrier structure is preferably formed from the electrically insulating base body and the conductor structure. The use of conductor bodies and insulating bodies which are of substantially the same size advantageously enables the carrier structure to be formed by additive methods. Rapid and low cost production of the carrier structure is thus possible.

It is possible for material compositions of the insulating bodies to differ from one another individually or in groups. It is thus possible, by mixing insulating bodies with various material compositions, to adapt one or more physical properties of the base body and hence of the carrier structure.

According to at least one embodiment of the carrier structure, the conductor bodies and/or the insulating bodies are spherical. The conductor bodies and/or the insulating bodies are preferably arranged at least in part in a densest possible sphere packing configuration or in the manner of a densest possible sphere packing configuration. The proportion of conductor bodies in a total volume of the conductor structure is, for example, at least 60% or at least 65% or at least 70%. The proportion of insulating bodies in a total volume of the base body is, for example, 60% or at least 65% or at least 70%. For example, the conductor bodies and/or the insulating bodies are arranged in a hexagonal sphere packing configuration or in the manner of a hexagonal sphere packing configuration. Arrangement in a packing configuration in the manner of a densest possible sphere packing configuration enables the conductor bodies and/or the insulating bodies to be packed particularly densely and enables the conductor structure to be made mechanically stable.

According to at least one embodiment of the carrier structure, this has at least one cavity, in which electrical components can be arranged. For example, electrical components can be arranged in the cavity in such a way that the components do not project beyond the carrier structure and/or end flush with a main side of the carrier structure. For example, the electrical components are in direct contact with the first and/or the second connecting means and are preferably connected materially to the carrier structure.

According to at least one embodiment of the carrier structure, gaps between the conductor bodies and/or the insulating bodies are filled with the first and the second connecting means, respectively. In particular, the gaps are filled completely with the first and/or second connecting means. The complete filling of gaps makes it possible to avoid the cavities, also referred to as voids, in the carrier structure. It is thereby possible to enhance thermal properties and the robustness of the carrier structure.

A method for producing a carrier structure is furthermore specified. By means of the method, it is possible, in particular, to produce a carrier structure described here. That is to say that all the features disclosed for the method are also disclosed for the carrier structure and vice versa.

In at least one embodiment, the method comprises providing a base carrier. The base carrier is formed by a ceramic, a silicone or Teflon, for example.

In a further method step, first spherical elements and second spherical elements are applied to the base carrier. Each first spherical element has a conductor body and a first connecting means as a sheath, for example. The conductor body is of spherical design, for example, and has a diameter of between 1 μm and 50 μm, inclusive. The first connecting means surrounds the conductor body, preferably completely on all sides. The first connecting means has a thickness on the conductor body of between 1 μm and 10 μm, inclusive, for example. The conductor body and the first connecting means are formed by one of the above-described materials, for example.

For example, every second spherical element has an insulating body and a second connecting means as a sheath. The insulating body is of spherical design, for example, and has a diameter of between 1 μm and 50 μm, inclusive. The second connecting means surrounds the insulating body, preferably completely on all sides. The second connecting means has a thickness of between 1 μm and 10 μm, inclusive, for example. The insulating body and the second connecting means are formed by one of the above-described materials, for example.

When applying the first and second spherical elements, it is the case, in particular, that each first spherical element is arranged adjacent to at least one further first spherical element, and each second spherical element is arranged adjacent to at least one further second spherical element. It is possible for at least some first spherical elements additionally to be arranged adjacent to a second spherical element and vice versa.

In a further method step, the first spherical elements and the second spherical elements are connected to the carrier structure. In this process, the conductor bodies, together with the first connecting means, form at least one conductor structure of the carrier structure. The insulating bodies of the second spherical elements, together with the second connecting means, form at least one base body of the carrier structure.

The spherical elements are connected by means of a hardening or soldering process, for example. To connect the first spherical elements and the second spherical elements, the arrangement of first and second spherical elements is, in particular, heated, with the result that the first and the second connecting means are at least partially melted, and connect the conductor bodies and the insulating bodies to one another. A temperature at which the first and second spherical elements can be appropriately processed is, for example, between 100° C. and 300° C., inclusive.

During the connection of the spherical elements, a volume of the arrangement of the spherical elements is, in particular, reduced. If, for example, the spherical elements are arranged in a densest possible sphere packing configuration or in the manner of a densest possible sphere packing configuration, a total volume of gaps between the spherical elements is between 20% and 40%, inclusive, of a total volume of the arrangement, for example. During the connection of the spherical elements, these cavities are at least partially filled by the first and second connecting means, for example. Accordingly, a finished carrier structure has a volume which is, for example, 30% or 25% or 20% less than a volume of the arrangement comprising the first and second spherical elements before connection.

By means of the method described here, it is possible to produce carrier structures for electronic components at low cost. The application of electrically conductive first spherical elements with diameters of between 1 μm and 80 μm, inclusive, furthermore makes it possible to implement small structure sizes. By means of the formation of the base body, it is furthermore possible to form a mechanically stable carrier structure.

According to at least one embodiment of the method, first spherical elements and second spherical elements connected in a further method step are at least partially combined. For example, a carrier structure originating from the connection of the first spherical elements and the second spherical elements is heated, wherein the first connecting means combines at least partially with the conductor bodies. Such a heat treatment is also known by the English term “tempering”. A melting point of the conductor structure and/or of the overall carrier structure can thereby be increased. A melting point of the carrier structure following the heat treatment is at least 500° C., for example.

According to at least one embodiment, the spherical elements are applied to the carrier structure after the connection of the first and second spherical elements. It is thereby advantageously possible to extend the carrier structure. That is to say that the method steps according to which first and second spherical elements are applied and according to which first and second spherical elements are connected to one another can be carried out multiple times in succession. The optional method step in which the first and/or second spherical elements are at least partially combined can likewise be carried out multiple times. By applying further spherical elements, it is possible, for example, to form a cavity for electrical components in the carrier structure.

According to at least one embodiment of the method, each first spherical element is arranged in direct contact with another first spherical element. In particular, each second spherical element is arranged in direct contact with another second spherical element. The first and second spherical elements are preferably arranged in a densest possible sphere packing configuration or in the manner of a densest possible sphere packing configuration. By means of such an arrangement, it is possible to pack the conductor structures of the first spherical elements and the insulating bodies of the second spherical elements particularly densely in the finished carrier structure.

According to at least one embodiment of the method, gaps between the conductor bodies and/or the insulating bodies are completely filled during the connection of the spherical elements.

According to at least one embodiment of the method, an adhesive agent layer is applied to the base carrier before the application of the first spherical elements. The adhesive agent layer is, for example, a flux, a PDMS adhesive layer, a thermoplastic adhesive layer or a thin adhesive layer. As a result of the adhesive agent layer, the first and second spherical elements do not change position on the base carrier during the method, or do so only to an insignificant extent. The adhesive agent layer preferably volatilizes during the connection of the spherical elements, e.g. by vaporization. It is also possible that residues of the adhesive agent layer will remain in the carrier structure.

According to at least one embodiment of the method, n layers of spherical elements are applied to the base carrier, where n is a natural number greater than 1. In particular, a layer of spherical elements has a thickness which corresponds substantially to the thickness of one spherical element. By applying a plurality of layers of spherical elements, it is possible to build up three dimensional conductor structures and a three dimensional base body of the carrier structure.

According to at least one embodiment of the method, before an n^{th} layer of spherical elements is applied, an n^{th} adhesive agent layer is applied to the (n−1)^{th} layer of spherical elements, where n continues to be a natural number greater than 1. By virtue of the adhesive agent layer between two adjacent layers of spherical elements, the spherical elements in this layer remain in their position defined by application and do not change this position significantly during the method.

According to at least one embodiment of the method, at least one electrical component is mounted on the carrier structure. For example, the electrical component is mounted in a cavity of the carrier structure.

The mounting of the electrical component can take place after the finishing of the carrier structure. However, the electrical component can preferably be applied before the ultimate finishing of the carrier structure. In this case, the first and second connecting means can serve as an adhesive agent or solder for the electrical component. In particular, the first connecting means forms a solder for the electrical contacting of the electrical component. The second connecting means connects the electrical component permanently and materially to the carrier structure, for example.

A device for carrying out a method described here is furthermore specified. In particular, the device is configured to apply spherical elements to the base carrier. That is to say that all the features disclosed for the device are also disclosed for the method and vice versa.

According to at least one embodiment, the device comprises a downtube and a sphere outlet. For example, the downtube has an inside diameter which is at most 1.9 times as large as a diameter of the first and second spherical elements. That is to say that the inside diameter of the downtube is configured in such a way that only one spherical element can pass through the downtube at one time.

According to at least one embodiment of the device, said device comprises a feed mechanism for feeding a spherical element from the downtube to the sphere outlet. In particular, the device is configured in such a way that a single spherical element can be fed to the sphere outlet from a container containing first and/or second spherical elements through the downtube and the feed mechanism at any one point in time. Thus, the spherical elements can be arranged individually and in succession on the base carrier.

According to at least one embodiment of the device, the feed mechanism has a blocking element between the downtube and the sphere outlet. The blocking element is used, in particular, to stop feeding of spherical elements to the sphere outlet.

According to at least one embodiment of the device, the blocking element is configured in such a way that, in a first state, it at least partially closes the downtube, thus making it impossible for a spherical element to be guided from the downtube to the sphere outlet. In a second state, an interior of the downtube is free from the blocking element, thus enabling a spherical element to be guided through the downtube to the sphere outlet. That is to say that the blocking element allows selective feeding of spherical elements to the sphere outlet. When, during the production of the carrier structure, the device is moved over the base carrier, for example, in order to apply spherical elements to the base carrier, the blocking element can be used to define at what points a spherical element is applied to the base carrier.

According to at least one embodiment, the blocking element is a rotatably mounted perforated disk. By way of example, the perforated disk has at least one opening, the diameter of which is larger than the diameter of a spherical element. The perforated disk is, for example, mounted so as to be rotatable about an axis which runs parallel to a main direction of extent of the downtube. In the second state, in which the interior of the downtube is free from the blocking element, the opening of the perforated disk is pushed into the downtube, for example. In the second state, a different region of the perforated disk is arranged in the downtube, for example, as a result of which the perforated disk blocks the downtube.

According to at least one embodiment, the blocking element comprises a bimetallic strip with a heating element. The bimetallic strip is formed by two metals with different coefficients of thermal expansion. The heating element is configured to heat the bimetallic strip and to deform the bimetallic strip by virtue of the different coefficients of thermal expansion of the metals. In an undeformed first state, the bimetallic strip projects into the downtube and partially closes it, for example. When the heating element is heated and the bimetallic strip is deformed, the downtube is free from the bimetallic strip in a second, deformed state of the bimetallic strip, and spherical elements can pass through the downtube.

According to at least one embodiment, the blocking element comprises a piezoelectric element with a voltage source. For example, the first state of the blocking element is implemented if an electrical voltage is applied to the piezoelectric element and the piezoelectric element is expanded. The second state of the blocking element is implemented, for example, if no voltage is applied to the piezoelectric element. In the first state, the piezoelectric element is expanded, for example, and projects into the downtube.

According to at least one embodiment, the blocking element comprises an expansion element with a heating element. The heating element is configured to heat the expansion element. The first state of the blocking element is achieved, for example, by heating the heating element, with the expansion element expanding into the downtube. The expansion element comprises, for example, copper with the coefficient of expansion of 18 ppm/K, which is at least partially sheathed by a thermal insulator. By applying a current by means of the heating element, it is possible to heat the expansion element by 200 K, for example. In this way, an elongation of, for example, 3600 ppm can be achieved.

According to at least one embodiment of the device, an intermediate piece is arranged between the downtube and the sphere outlet, wherein a main direction of extent of the intermediate piece is transverse, in particular perpendicular, to a main direction of extent of the downtube. A pulse generator, for example, is arranged at a first end of the intermediate piece. The sphere outlet, in particular, is arranged at a second end of the intermediate piece, said end being opposite the first end. The downtube is preferably arranged at a central opening between the first end and the second end of the intermediate piece.

In this embodiment, the device is configured to feed a spherical element to the intermediate piece through the central opening via the downtube. The spherical element can be conveyed to the sphere outlet by means of the pulse generator. The spherical element falls from the downtube into the intermediate piece on account of gravity, for example. In order to reach the sphere outlet, a pulse is transmitted to the spherical element by the pulse generator during operation, and the spherical element is conducted to the sphere outlet.

According to at least one embodiment, the pulse generator comprises a liquid container having a flexible diaphragm and a heating element. The diaphragm is, in particular, arranged at the first end of the intermediate piece. The liquid container is preferably gastight, thus preventing any liquid from escaping from the liquid container.

In particular, the pulse generator is configured to transmit a pulse to a spherical element in the intermediate piece via the diaphragm by heating a liquid in the liquid container. In particular, heating the liquid by means of the heating element causes expansion of the liquid, resulting in stretching of the diaphragm. The extension of the diaphragm leads to a pulse being transmitted to the spherical element, and the spherical element is fed to the sphere outlet.

According to at least one embodiment, the pulse generator comprises a liquid container having a nozzle, a first heating element and a second heating element. The nozzle is arranged at the first end of the intermediate piece. The first heating element is configured to direct a liquid droplet through the nozzle into the intermediate piece. This takes place, for example, on the basis of thermal expansion of the liquid in the liquid container. The second heating element is situated opposite the nozzle in the intermediate piece and is, for example, configured to vaporize the liquid droplet and to expand a gas bubble that forms. The expansion of the gas bubble leads to a pulse being transmitted to the spherical element in the intermediate piece, and the spherical element is fed to the sphere outlet.

A printhead is furthermore specified. The printhead is suitable, in particular, for carrying out a method described here. Furthermore, the printhead comprises a multiplicity of devices described here for carrying out the method. That is to say that all the features disclosed for the method and the device are also disclosed for the printhead and vice versa.

According to at least one embodiment of the printhead, said printhead comprises a multiplicity of devices, wherein sphere outlets of the devices are arranged at the nodes of a regular grid. By means of the printhead, it is possible to arrange a multiplicity of first and second spherical elements on the base carrier.

Further advantages and advantageous embodiments and developments of the carrier structure of the method, of the device and of the printhead will become apparent from the exemplary embodiments which are presented below in conjunction with schematic drawings. In the figures, elements which are identical, are of the same kind or act in the same way are provided with the same reference signs. Fundamentally, the figures and the size ratios of the elements illustrated in the figures relative to one another should not be considered to be to scale. On the contrary, individual elements may be shown on an exaggeratedly large scale to enable them to be illustrated more clearly and/or understood better.

### BRIEF DESCRIPTION OF THE DRAWINGS

In the drawings:

FIGS. 1A to 1E show schematic sectional views of various stages of one exemplary embodiment of a method for producing a carrier structure;

FIG. 2 shows a schematic sectional view of a carrier structure described here according to one exemplary embodiment;

FIGS. 3A and 3B show schematic sectional views of optional method steps of a method for producing a carrier structure according to further exemplary embodiments;

FIG. 4 shows a schematic sectional view of a carrier structure described here according to one exemplary embodiment, with an electrical component;

FIGS. 5A and 5B show schematic sectional views of first and second spherical elements which are used in a method described here;

FIGS. 6A to 7B show detail views of arrangements of spherical elements of the kind used in the method described here;

FIGS. 8A to 10C show schematic sectional views of a device for carrying out a method described here according to several exemplary embodiments; and

FIG. 11 shows a plan view of a printhead described here according to one exemplary embodiment.

### DETAILED DESCRIPTION OF ILLUSTRATIVE EMBODIMENTS

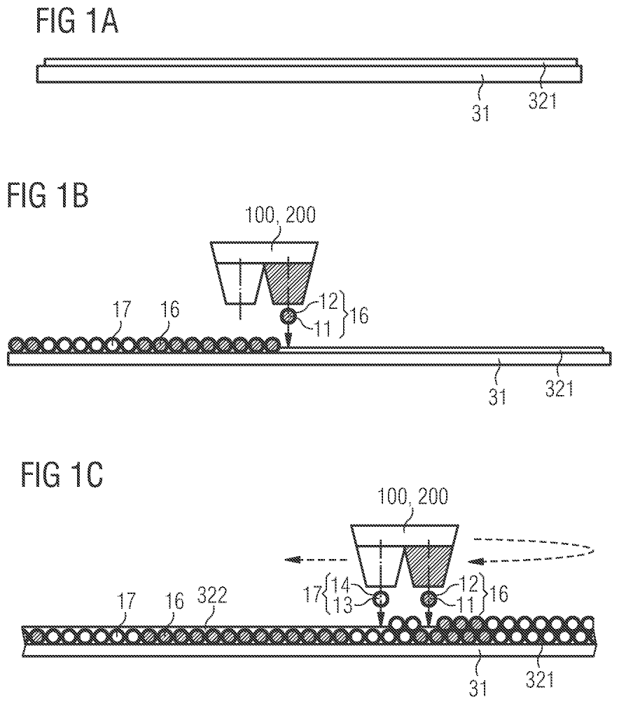

In the method according to the exemplary embodiment in FIGS. 1A to 1E, a base carrier 31 is prepared. An adhesive agent layer 321 is applied to the base carrier 31 (FIG. 1A). The base carrier 31 is formed by a ceramic, a silicone or Teflon, for example. The adhesive agent layer 321 comprises a flux, for example.

First spherical elements 16 and second spherical elements 17 are applied to the base carrier 31 by means of a printhead 200, which comprises a device 100 for applying the spherical elements 16, 17 (FIG. 1B). The first spherical elements 16 and the second spherical elements 17 are each of spherical design. In particular, the first and second spherical elements 16, 17 have the same diameter. The diameter is 30 μm, for example.

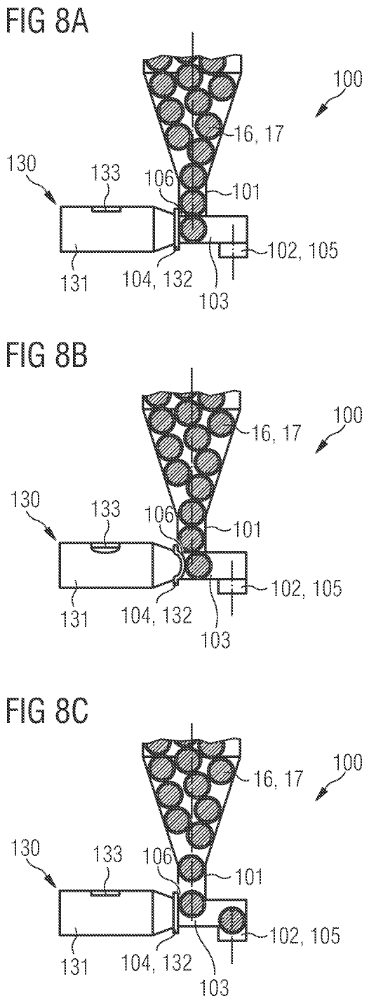

Each first spherical element 16 has a conductor body 11 and a first connecting means 12 as a sheath for the conductor body 11, see also FIG. 5A. The conductor body 11 and the first connecting means 12 are formed by an electrically conductive material. The conductor body 11 is of spherical design, for example. The conductor body 11 has a diameter of 20 μm, for example. The first connecting means 12 has a thickness of 5 μm, for example, on the conductor body 11. The conductor body 11 comprises one of the following metals, for example: nickel, iron, tin, aluminum, tungsten. The first connecting means 12 is formed by tin, for example, or comprises a solder material containing tin, e.g. an SnCu solder.

The second spherical elements 17 are, for example, each formed by an insulating body 13 with a sheath consisting of the second connecting means 14 applied to the insulating body 13, see also FIG. 5B. The insulating body 13 is, for example, of spherical design and has a diameter of 20 μm. The second connecting means 14 has a thickness on the insulating body of 5 μm, for example. The insulating body 17 and the second connecting means 14 are formed by an electrically insulating material, for example. The insulating body 17 comprises, for example, a ceramic, such as Al₂O₃, AlN, SiC or a glass, such as SiO₂ or a plastics material. The second connecting means 14 is formed by a thermoplastic or a thermoset, for example.

In the method step illustrated in FIG. 1B, the first spherical elements 16 and the second spherical elements 17 are applied to the base body 31 by means of the device 100. In this process, the printhead 200 moves over the base carrier 31 and places spherical elements 16, 17 at predetermined points. In this process, the first spherical elements 16 are arranged in such a way that each first spherical element 16 is arranged directly adjacent to a further spherical element 16. The second spherical elements 17 are arranged in such a way that each spherical element 17 is in direct contact with a further spherical element 17. The adhesive agent layer 321 is used to ensure that the spherical elements 16, 17 remain in their position on the base carrier 31.

In a further step of the method, a further layer of spherical elements 16, 17 is arranged on a first layer of spherical elements 16, 17 (FIG. 1C). A second adhesive agent layer 322 is arranged between the first layer of spherical elements 16, 17 and the second layer of spherical elements 16, 17. The second adhesive agent layer 322 prevents shifting of positions of the spherical elements 16, 17 in the second layer. The spherical elements 16, 17 are arranged in a densest possible sphere packing configuration or in the manner of a densest possible packing configuration.

FIG. 1D illustrates a stage of the method in which four layers of spherical elements 16, 17 have been applied to the base carrier 31. For this purpose, the step illustrated in FIG. 1C was repeated several times.

In a further step of the method, the spherical elements 16, 17 are connected to one another (FIG. 1E). Connection is accomplished, in particular, by melting the first and second connecting means 12, 14. In this process, the arrangement of the first and second spherical elements 16, 17 is, for example heated to a temperature of between 200° C. and 300° C., inclusive. For example, an epoxy adhesive as a second connecting means 14 can be combined with an SnCu solder as a first connecting means 12. The epoxy adhesive cures at 120ºC, for example, and the SnCu solder melts at 250° ° C., for example. Connection then takes place at 250° C., for example. The epoxy adhesive then cures at 250° C., although 120° C. would be sufficient for curing.

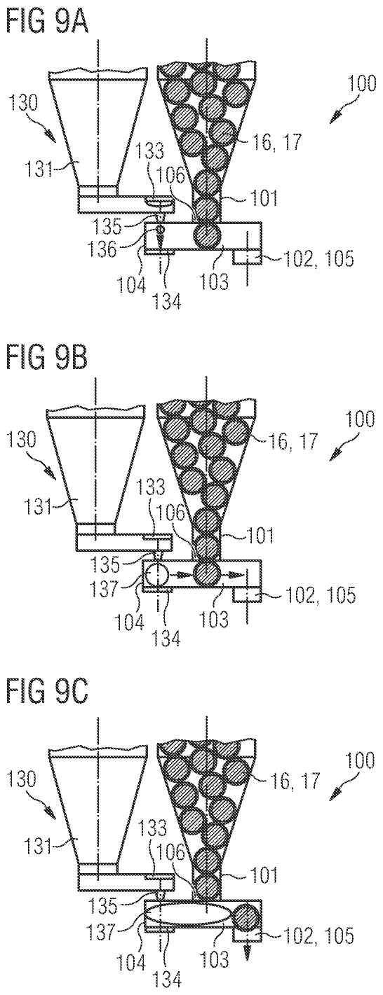

The connection of the spherical elements 16, 17 produces a carrier structure 1. The carrier structure 1 comprises a conductor structure 2, which is formed by the conductor bodies 11 together with the first connecting means 12, and a base body 3, which is formed by the insulating bodies 13 together with the second connecting means 14. By means of the connection of the spherical elements 16, 17, cavities between the spherical elements 16, 17 are filled with the first and second connecting means 12, 14. In this process, gaps 15 are completely filled, for example, see also FIGS. 6A and 6B, or partially filled, see also FIGS. 7A and 7B. Owing to the filling of the gaps, the carrier structure 1 has a smaller volume than the arrangement of the first and second spherical elements 16, 17. A height of the arrangement consisting of the spherical elements 16, 17 above the base carrier 31 is reduced by 10% to 25%, for example.

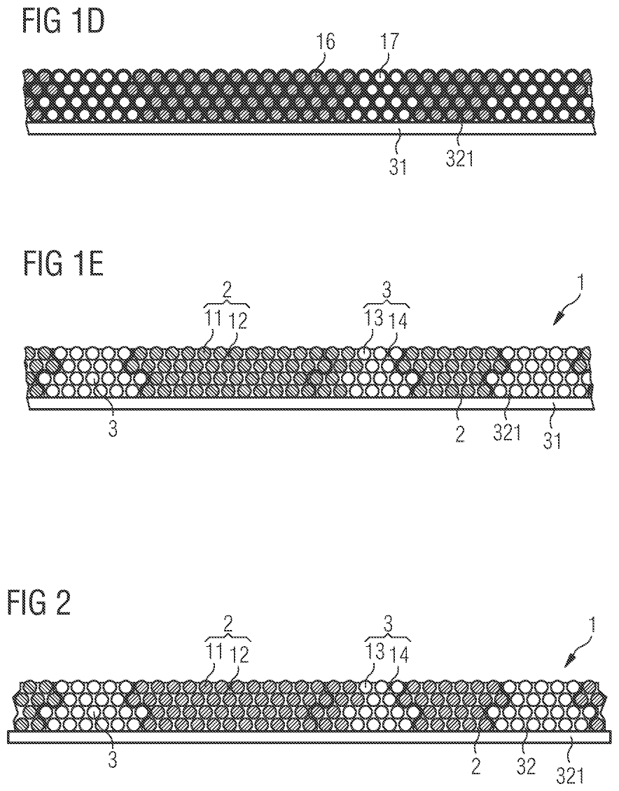

In the exemplary embodiment of the carrier structure 1 according to FIG. 2, the conductor bodies 11 have been at least partially combined with the first connecting means 12 in order to increase a melting point of the carrier structure 1. For example, the melting point of the carrier structure 1 is increased to at least 500° C. In particular, the carrier structure 1 of FIG. 2 forms a lead frame.

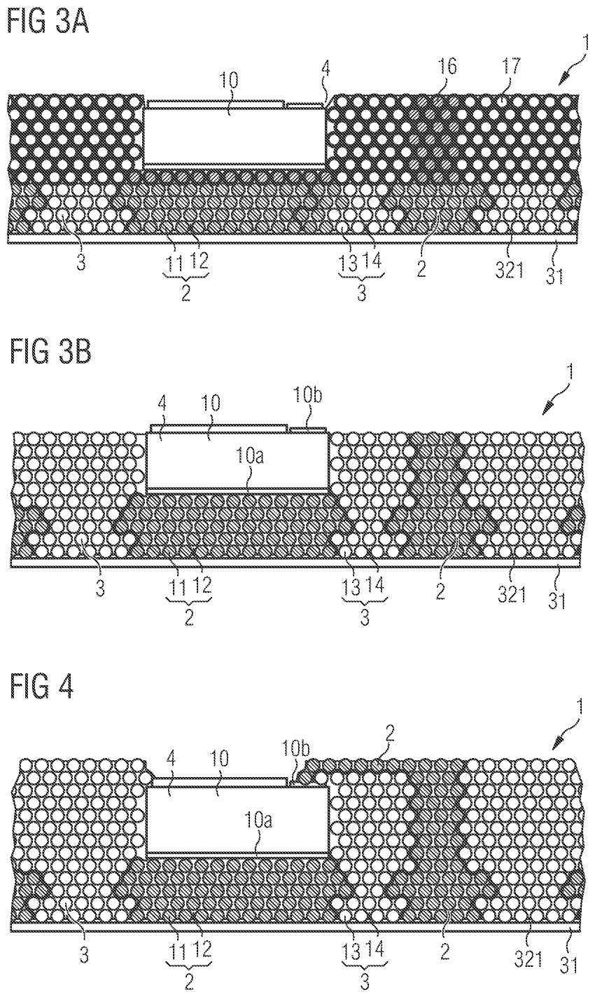

The method stages in FIGS. 3A and 3B illustrate method steps which can be carried out on a carrier structure 1 according to FIG. 1E or 2. On the carrier structure 1 in FIG. 2, for example, further first and second spherical elements 16, 17 are arranged (FIG. 3A). The arrangement of the spherical elements takes place in a manner similar to that explained in connection with FIG. 1C. The spherical elements 16, 17 are arranged in such a way that a cavity 4 is formed. An electrical component 10 is arranged in the cavity 4. The electrical component 10 is, for example, an optoelectronic semiconductor chip for generating or detecting electromagnetic radiation, an integrated circuit, a resistor or a capacitor.

After the arrangement of the electronic component 10, the spherical elements 16, 17 that have been arranged on the carrier structure 1 in FIG. 2 are connected to one another (FIG. 3B). The conductor structures 2 and the base body 3 are thereby extended, and a carrier structure 1 is produced. The electrical component 10 is arranged in the cavity 4 in the carrier structure 1. On a side of the electrical component 10 facing the base carrier 31, said component has a first electrical contact surface 10a, which is connected in an electrically conductive manner to a conductor structure 2 of the carrier structure 1. Here, the first connecting means 12 serves as a solder material. Via the first and second connecting means 12, 14, the electrical component 10 is connected materially to the carrier structure 1.

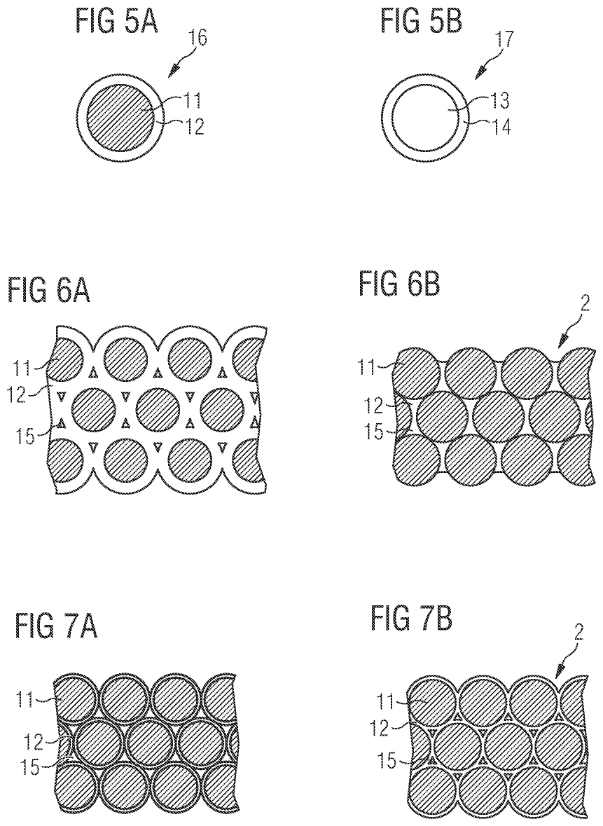

In the exemplary embodiment of FIG. 4, the carrier structure 1 has a conductor structure 2 which extends completely through the base body 3 and which, in contrast to the carrier structure 1 in FIG. 3B, extends on a main side of the carrier structure 1, which main side faces away from the base carrier 31. This conductor structure 2 is connected in an electrically conductive manner to a second electrical contact surface 10b of the electrical component 10. In other respects, the statements made in relation to the carrier structure 1 in FIG. 3B apply analogously to the carrier structure in FIG. 4.

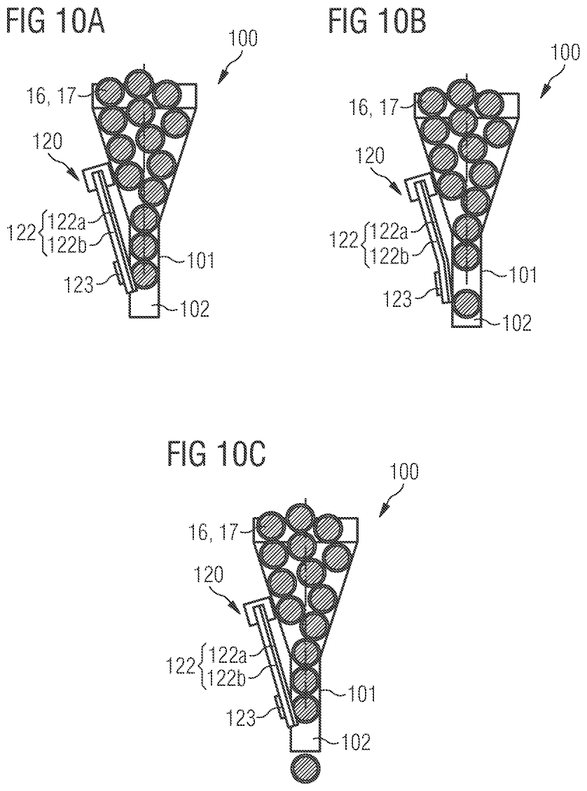

FIGS. 8A to 8C illustrate a device for carrying out the method according to a first exemplary embodiment and the mode of operation of said method. The device 100 comprises a downtube 101. A spherical element 16, 17 can be fed to a sphere outlet 102 through the downtube 101. Here, an inside diameter of the downtube 101 is at most 20% greater than a diameter of a spherical element 16, 17.

An intermediate piece 103 is arranged between the downtube 101 and the sphere outlet 102. A main direction of extent of the intermediate piece 103 is perpendicular to a main direction of extent of the downtube 101.

The sphere outlet 102 is arranged at a second end 105 of the intermediate piece 103. A pulse generator 130 is arranged at a first end 104 of the intermediate piece 103, which is situated opposite the second end 102. Via a central opening 106, which is arranged between the first end 104 and the second end 105, spherical elements 16, 17 are fed from the downtube 101 to the intermediate piece 103 during the operation of the device 100. In this process, the spherical elements 16, 17 are fed singly to the intermediate piece.

The pulse generator 130 has a liquid container 131 containing a liquid. A diaphragm 132 is arranged between the liquid container 131 and the first end 104. The pulse generator 130 furthermore comprises a heating element 133. The liquid container is preferably gastight, thus preventing any liquid from escaping from the liquid container.

During operation of the device 100 as intended, a spherical element 16, 17 passes from the downtube into the intermediate piece 103 (FIG. 8A).

The heating element 133 is configured to heat the liquid in the liquid container 131. As a result of the heating of the liquid in the liquid container 131, the liquid expands, and the flexible diaphragm 132 is stretched (FIG. 8B). Owing to the deformation of the diaphragm 132, a pulse is transmitted to the spherical element 16, 17 in the intermediate piece 103.

By means of the transmission of the pulse from the diaphragm 132 to the spherical element 16, 17, the spherical element 16, 17 in the intermediate piece 103 is guided to the sphere outlet 102 (FIG. 8C).

By heating the heating element 133, it is accordingly possible to place a spherical element 16, 17 at a desired point on the base carrier 31, see also FIG. 1B.

The device 100 according to FIGS. 9A to 9C differs from the device according to FIGS. 8A to 8C in that the pulse generator 130 comprises two heating elements 133, 134 and a nozzle 135. In operation as intended, the first heating element 133 heats a liquid in the liquid container 131, as a result of which a liquid droplet 136 passes through the nozzle 135 into the intermediate piece 103 (FIG. 9A).

A second heating element 134, situated opposite the nozzle 135, in the region of the first end 104 is configured to vaporize the liquid droplet 136. During this process, a gas bubble 137 forms (FIG. 9B).

As a result of further heating by means of the second heating element 134, the gas bubble 137 expands and transmits a pulse to a spherical element 16, 17, which is situated in the intermediate piece 103 (FIG. 9C). This pulse transmission guides the spherical element 16, 17 to the sphere outlet 102.

FIGS. 10A to 10C illustrate a device 100 which comprises a blocking element 120. The blocking element 120 is arranged partially in a downtube 101 and closes the downtube 101 at least partially toward the sphere outlet 102. The blocking element 120 comprises a bimetallic strip 122 with a first metal 122a and a second metal 122b. The first metal 122a and the second metal 122b differ in respect of their coefficient of thermal expansion. A heating element 123 is arranged on the second metal 122b.

In a first state of the blocking element 120, the bimetallic strip 122 closes the downtube at least partially toward the sphere outlet (FIG. 10A). In the first state, the bimetallic strip does not have any curvature or deformation, and is straight.

In a second state, the bimetallic strip is deformed and does not extend into the downtube 101 (FIG. 10B). The downtube 101 is thus free from the blocking element 120. In the second state, spherical elements 16, 17 can pass through the downtube and reach the sphere outlet 102. The deformation of the bimetallic strip is achieved, in particular, by heating of the heating element 123.

By cooling the bimetallic strip 122 it is possible to bring the bimetallic strip 122 back into the first state, whereby the downtube is once again blocked for spherical elements 16, 17 (FIG. 10C).

By heating with the heating element 123, it is thus possible to open and close the sphere outlet 102 selectively for spherical elements 16, 17. It is thus possible to place spherical elements 16, 17 in a targeted manner on the base carrier 31, see also FIG. 1B.

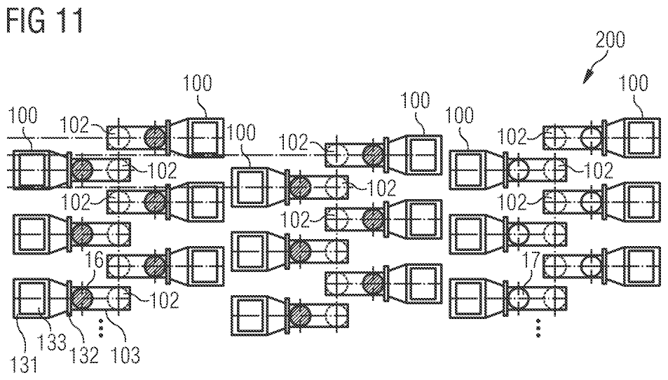

FIG. 11 illustrates a printhead 200 in a plan view of the base carrier 31 (not depicted in FIG. 11). The printhead 200 has a multiplicity of devices 100 according to FIGS. 8A to 8C. The sphere outlets 102 of the device 100 are arranged at the nodal points of a regular rectangular grid. The devices 100 can each be operated individually and independently of one another. By means of the printhead 200, it is possible to arrange a multiplicity of first and second spherical elements 16, 17 in parallel on the base carrier 31, see also FIG. 1C. Rapid and low cost production of a carrier structure 1 is thus possible.

The description with reference to the exemplary embodiments does not limit the invention to these embodiments. On the contrary, the invention includes any novel feature and combination of features, including, in particular, any combination of features in the patent claims, even if said feature or said combination is itself not specified explicitly in the patent claims or exemplary embodiments.

1-17. (canceled)

18. A carrier structure comprising:
at least one conductor structure configured for electrically contacting electrical components,
wherein the conductor structure comprises a plurality of conductor bodies,
wherein at least some of the conductor bodies are in direct contact with electrically conductive first connectors, and
wherein the conductor structure comprises the conductor bodies and the first connectors.

19. The carrier structure of claim 18, further comprising a plurality of insulating bodies, wherein at least some of the insulating bodies are in direct contact with electrically insulating second connectors, and
wherein the insulating bodies, together with second connectors, form an electrically insulating base body of the carrier structure.

20. The carrier structure of claim 19, wherein the conductor bodies and/or the insulating bodies are spherical and are arranged at least in part in a densest possible sphere packing configuration or in a manner of a densest possible sphere packing configuration.

21. The carrier structure of claim 18, further comprising at least one cavity, in which electrical components are arrangeable.

22. The carrier structure of claim 18, further comprising gaps located between the conductor bodies are filled with the first connectors.

23. A method for producing a carrier structure, the method comprising:
providing a base carrier;
applying first spherical elements and second spherical elements,
wherein each first spherical element has a conductor body and a first connector as a sheath,
wherein each second spherical element has an insulating body and a second connector as a sheath,
wherein each first spherical element is arranged adjacent to at least one further first spherical element, and
wherein each second spherical element is arranged adjacent to at least one further second spherical element; and
connecting the first spherical elements and the second spherical elements to the carrier structure,
wherein the conductor bodies, together with the first connectors, form at least one conductor structure of the carrier structure, and
wherein the insulating bodies, together with the second connectors, form at least one base body of the carrier structure.

24. The method of claim 23,
wherein each first spherical element is arranged in direct contact with another first spherical element, and
wherein each second spherical element is arranged in direct contact with another second spherical element.

25. The method of claim 23, further comprising completely filling gaps between the conductor bodies and/or the insulating bodies during connection of the spherical elements.

26. The method of claim 23, further comprising applying a first adhesive agent layer to the base carrier before applying the first spherical elements.

27. The method of claim 26,
wherein n layers of spherical elements are applied to the base carrier,
wherein, before an n-th layer of spherical elements is applied, an n-th adhesive agent layer is applied to an (n−1)-th layer of spherical elements, and
wherein n is a natural number greater than 1.

28. A device comprising:
a downtube and a sphere outlet,
wherein the downtube has an inside diameter which is at most 1.9 times as large as a diameter of a spherical element, the spherical element being the first spherical element or the second spherical element; and
a feed mechanism configured for feeding the spherical element from the downtube to the sphere outlet,
wherein the device is configured for performing the method of claim 23.

29. The device of claim 28,
wherein the feed mechanism has a blocking element between the downtube and the sphere outlet,
wherein the blocking element is configured such that
in a first state, it at least partially closes the downtube thereby making it impossible for the spherical element to be guided from the downtube to the sphere outlet, and
in a second state, an interior of the downtube is free from the blocking element thereby enabling the spherical element to be guided through the downtube to the sphere outlet.

30. The device of claim 29, wherein the blocking element comprises:
a rotatably mounted perforated disk,
a bimetallic strip with a heating element,
a piezoelectric element with a voltage source, or
an expansion element with a heating element.

31. The device of claim 28, further comprising:
an intermediate piece arranged between the downtube and the sphere outlet,
wherein a main direction of an extent of the intermediate piece is transverse to a main direction of extent of the downtube,
wherein a pulse generator is arranged at a first end of the intermediate piece,
wherein the sphere outlet is arranged at a second end of the intermediate piece, the end being opposite the first end,
wherein the downtube is arranged at a central opening between the first end and the second end of the intermediate piece,
wherein the device is configured such that the downtube feeds the spherical element to the intermediate piece through the central opening, and
wherein the spherical element is conveyable to the sphere outlet by the pulse generator.

32. The device of claim 31,
wherein the pulse generator comprises a liquid container having a flexible diaphragm and a heating element,
wherein the diaphragm is arranged at the first end of the intermediate piece, and
wherein the pulse generator is configured to transmit a pulse to a spherical element in the intermediate piece via the diaphragm by heating a liquid in the liquid container.

33. The device of claim 31,
wherein the pulse generator comprises a liquid container having a nozzle, a first heating element and a second heating element,
wherein the nozzle is arranged at the first end of the intermediate piece,
wherein the first heating element is configured to direct a liquid droplet through the nozzle into the intermediate piece, and
wherein the second heating element is configured to vaporize the liquid droplet and to expand a forming gas bubble.

34. A printhead comprising:
a plurality of devices, each device being the device of claim 28,
wherein sphere outlets of the devices are arranged at nodes of a regular grid.
